(19) United States
(12) Patent Application Publication
(10) Pub. No.: US 2017/0222096 A1
(43) Pub. Date: Aug. 3, 2017

(54) LED LIGHT SOURCE STRUCTURE AND PACKAGING METHOD

(71) Applicant: Shenzhen China Star Optoelectronics Technology Co., Ltd., Shenzhen, Guangdong (CN)

(72) Inventor: Yong FAN, Shenzhen, Guangdong (CN)

(73) Assignee: Shenzhen China Star Optoelectronics Technology Co., Ltd., Shenzhen, Guangdong (CN)

(21) Appl. No.: 14/775,521

(22) PCT Filed: Aug. 13, 2015
(86) PCT No.: PCT/CN2015/086816

§ 371 Date: Sep. 11, 2015

(30) Foreign Application Priority Data
Aug. 10, 2015 (CN) 201510487244.1

(51) Int. Cl. H01L 33/50; H01L 33/56; H01L 33/48

(52) U.S. Cl. CPC H01L 33/502; H01L 33/486; H01L 33/56; H01L 33/507; H01L 2933/0033; H01L 2933/0041

(57) ABSTRACT

An LED light source structure includes: a fixing bracket, an LED chip, a packaging gel and a quantum-dot glass box. The fixing bracket has a packaging slot and an installation slot from a bottom portion to a top portion of the fixing bracket, and a width of the installation slot is greater than a width of the packaging slot. The LED chip is packaged into the packaging slot by the packaging gel; the installation slot has a size matching with the quantum-dot glass box; the quantum-dot glass box is clamped and placed in the installation slot. The quantum-dot glass box includes a glass box and a quantum-dot fluorescent powder material, the glass box has a receiving cavity, and the quantum-dot fluorescent powder material is cured and packaged in the receiving cavity. A packaging method for the LED light source structure described above is also disclosed.

### BACKGROUND OF THE INVENTION

### 1. Field of the Invention

The present invention relates to a backlight module of a liquid crystal display, and more particularly to an LED light source structure using Quantum Dot (QD) and a packaging method for the same.

### 2. Description of Related Art

A liquid crystal display (LCD) has advantages of a thin size, low power consumption, no radiation, and so on so that an LCD is widely applied in the products such as mobile phones, digital cameras, computers, TV screen, and so on. Currently in the market, the LCD is mainly a backlight-type LCD, which includes a liquid crystal panel and a backlight module. The liquid crystal panel and the backlight module are disposed oppositely. The backlight module provides a display light source to the liquid crystal panel such that the liquid crystal panel can display an image. With the development of society, the demand for the quality of the backlight module by a user is higher. For improving the color saturation of a picture, through improving the chromaticity of a light bar of the backlight module, the color saturation of a picture can be improved. In the conventional art, a quantum-dot technology is utilized to improve the color gamut.

A Quantum Dot (QD) is also known as nanocrystal, and is formed by a limited number of atoms. In three dimensions, the size of the quantum dot is in nanometer scale. The quantum dot is usually made of a semiconductor material (usually II-VI element group or III-V element group), and made of a stable diameter of a nanoparticle ranged from 1 nm to 10 nm. A quantum dot can also be an altogether of atoms and molecules in a nanometer scale. A quantum dot can be formed by one kind of semiconductor material such as II and VI element group (for example: CdS, CdSe, CdTe, ZnSe, and so on), or III and V element group (for example: InP, InAs, and so on). A quantum dot can be formed by two kinds of or above semiconductors. A quantum dot is semiconductor nanostructure that bounds conduction band electrons, valence band holes and excitons in the three spatial directions. Because the orbitals of the bounds conduction band electrons and valence band holes are limited by quantum, a continuous band structure becomes an independent band structure having a molecular characteristic. After a quantum dot is excited, the quantum dot can emit florescent light. In the application of the quantum-dot technology in the lighting and display field, utilizing a property that the quantum dot can change a wavelength of an incident light to control wavelengths by different sizes of crystals. If a size of a crystal can be controlled precisely, a color can be controlled precisely and a luminous color range is very wide.

A Full Width at Half Maximum (FWHM) of a light emitting spectrum of a quantum dot is small, usually 20˜50 nm, which is a very good backlight source. A liquid crystal display device having quantum-dot fluorescent powders can increase 50% color gamut covering range comparing to a liquid crystal display device using YAG fluorescent powders such that the color of a liquid crystal display device is more brilliant, and the picture is more stereoscopic.

Currently, in the application of the quantum-dot fluorescent powders in an LED backlight source, after packaging an LED chip, the quantum-dot fluorescent powders and a silica gel are mixed to form a mixed gel. Through coating and other technologies, a thin film made of the quantum-dot fluorescent powders is formed on a light emitting surface of the LED chip. Because the quantum-dot fluorescent powders are easily to be oxidized so as to be failure and the thermal quenching phenomenon of the quantum-dot fluorescent powder is serious, with increasing temperature, luminous efficiency is decreased serious. Accordingly, in the conventional, directly coating the quantum-dot fluorescent powders on an LED chip in order to form a thin film lacks protection of the quantum-dot fluorescent powders. Therefore, the life of the quantum-dot fluorescent powders is shortened, the light emitting efficiency is low, and light color uniformity is poor.

### SUMMARY OF THE INVENTION

Accordingly, the present invention provides a quantum-dot glass box so as to form an effective protection for the quantum-dot power material in order to solve the problems of the short life of the quantum-dot fluorescent powders, low light emitting efficiency, and poor light color uniformity when applying the quantum-dot fluorescent powders in an LED chip.

In order to achieve the above purpose, the present invention adopts the following technology solution: a Light Emitting Diode (LED) light source structure, comprising: a fixing bracket having a packaging slot and an installation slot from a bottom portion to a top portion of the fixing bracket, wherein a width of the installation slot is greater than a width of the packaging slot; an LED chip; a packaging gel; and a quantum-dot glass box; wherein, the LED chip is packaged into the packaging slot by the packaging gel; the installation slot has a size matching with the quantum-dot glass box; the quantum-dot glass box is clamped and placed in the installation slot; wherein, quantum-dot glass box includes a glass box and a quantum-dot fluorescent powder material, the glass box has a receiving cavity, and the quantum-dot fluorescent powder material is cured and packaged in the receiving cavity.

Wherein, a wall thickness of the glass box is ranged from 0.1 mm to 0.7 mm.

Wherein, the quantum-dot fluorescent powder material includes a gel material and quantum-dot fluorescent powders mixed in the gel material.

Wherein, in the quantum-dot fluorescent powder material, a weight percentage of the quantum-dot fluorescent powders is ranged from 1% to 20%.

Wherein, the quantum-dot fluorescent powder is CdSe/ZnSe, CdSe/ZnS, CdS/ZnS, CdS/HgS, CdSe/ZnS/CdS, CdSe/CdS/ZnS, InP/CdS, CuInS or Graphene Oxide quantum dot.

Wherein, the gel material is an ultraviolet (UV) curable adhesive or an infrared (IR) curable adhesive.

Wherein, the LED chip includes a printed circuit board and an LED lamp electrically connected with the printed circuit board.

Wherein, the LED lamp is a blue LED lamp or an ultraviolet LED lamp.

Wherein, an upper surface of the packaging gel is not higher than a bottom of the installation slot, and the packaging gel is a silica gel.

Another aspect of the present invention provides a packaging method for above LED light source structure, comprising: (a) providing a fixing bracket, wherein the fixing bracket has a packaging slot and an installation slot from a bottom portion to a top portion of the fixing bracket, and a width of the installation slot is greater than a width of the packaging slot; (b) utilizing a packaging gel to package an LED chip into the packaging slot; and (c) clamping and placing a quantum-dot glass box in the installation slot.

Beneficial effects: the LED light source structure and the corresponding packaging method described above combine an LED light source with the quantum-dot technology. Wherein, the quantum-dot fluorescent powder material is cured and packaged in the glass box in order to resist water and moisture, prevent the quantum-dot fluorescent powders from being oxidized and failure, and extend the life of the quantum-dot fluorescent powders. Comparing to the conventional art, the present invention effectively solves the problems of the short life of the quantum-dot fluorescent powders, low light emitting efficiency, and poor light color uniformity.

### BRIEF DESCRIPTION OF THE DRAWINGS

FIG. 1 is a schematic diagram of an LED light source structure according to an embodiment of the present invention;

FIG. 2 is a schematic diagram of a fixing bracket of an LED light source structure according to an embodiment of the present invention;

FIG. 3 is a top cross-sectional view of a quantum-dot glass box according to an embodiment of the present invention;

FIG. 4 is a side cross-sectional view of a quantum-dot glass box according to an embodiment of the present invention;

FIG. 5 is a schematic diagram of a glass box before packaging a quantum-dot fluorescent powder material;

FIG. 6 is a process flow chart of a manufacturing method for a quantum-dot glass box according to an embodiment of the present invention; and

FIG. 7 is an exemplary illustration diagram of a packaging process of an LED light source structure according to an embodiment of the present invention.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

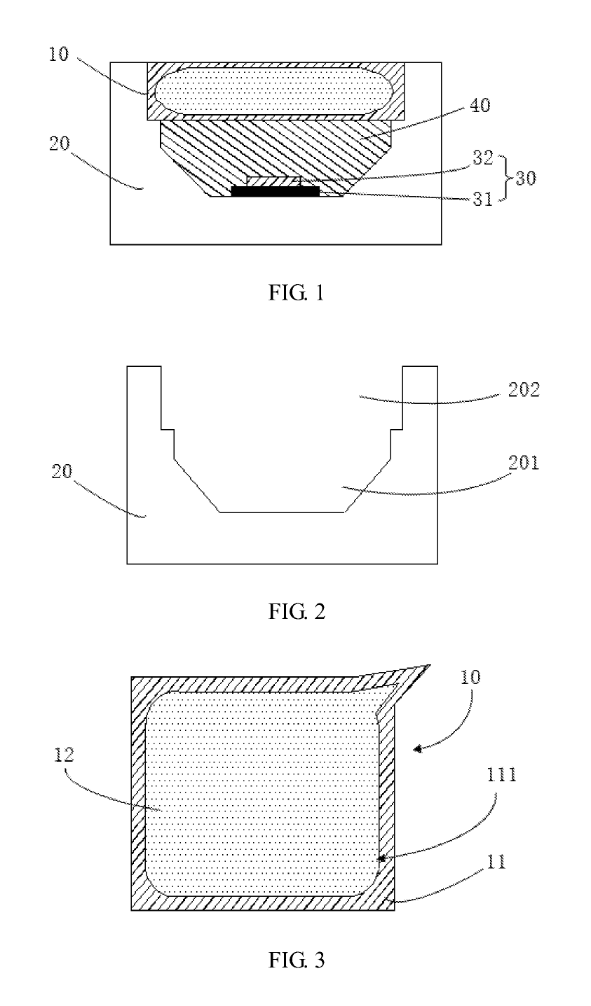

With reference to FIG. 1 and FIG. 2, the present embodiment provides an LED (Light-Emitting Diode) light source structure. The light source structure includes: a fixing bracket 20, an LED chip 30, a packaging gel 40 and a quantum-dot glass box 10.

Wherein, as shown in FIG. 2, from a bottom to a top, the fixing bracket 20 is sequentially provided with a packaging slot 201 and an installation slot 202. A width of the installation slot 202 is greater than a width of the packaging slot 201. A receiving space of the packing slot 201 located at a lower place is an inverted-trapezoid structure.

Wherein, as shown in FIG. 1, the LED chip 30 is packaged in the packaging slot 201 by the packaging gel 40. The installation slot 202 has a size matching with the quantum-dot glass box 10. The quantum-dot glass box 10 is clamped and placed in the installation slot 202. The light emitted from the LED chip 30 passes through the packaging gel and enters into the quantum-dot glass box 10. As a result, the quantum-dot fluorescent powder material in the quantum-dot glass box 10 is excited to emit a florescent light.

Wherein, as shown in FIG. 1, the LED chip 30 includes a printed circuit board 31 and an LED lamp 32 electrically connected with the printed circuit board 31. Specifically, the LED lamp 32 is a blue LED lamp or an ultraviolet LED lamp.

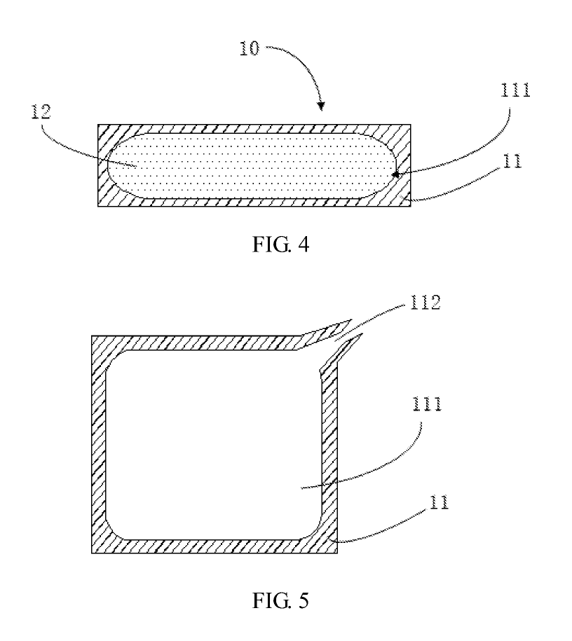

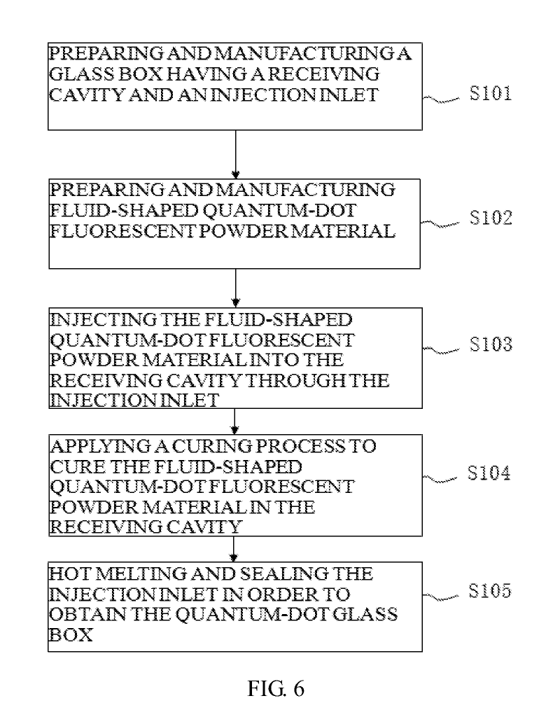

Furthermore, with reference to FIG. 3 and FIG. 4, the quantum-dot glass box 10 of the above embodiment includes a glass box 11 and a quantum-dot fluorescent powder material 12. Specifically, the glass box 11 has a receiving cavity 111, and the quantum-dot fluorescent powder material 12 is cured and packaged in the receiving cavity 111.

Wherein, as shown in FIG. 5, before packaging the quantum-dot fluorescent powder material 12 in the glass box 11, the glass box 11 has an injection inlet 112 communicated with the receiving cavity 111. Furthermore, a wall thickness of the glass box 11 is preferably ranged from 0.1 mm˜0.7 mm.

Wherein, the quantum-dot fluorescent powder material 12 includes a gel material and quantum-dot fluorescent powders mixed in the gel material. Specifically, in the quantum-dot fluorescent powder material 12, a weight percentage of the quantum-dot fluorescent powders can be selected from 1% to 20%. The quantum-dot fluorescent powder is one of quantum-dot fluorescent powders made of CdSe/ZnSe, CdSe/ZnS, CdS/ZnS, CdS/HgS, CdSe/ZnS/CdS, CdSe/CdS/ZnS, InP/CdS, CuInS and Graphene Oxide quantum dot. The gel material is an ultraviolet (UV) curable adhesive or an infrared (IR) curable adhesive. Wherein, because the quantum-dot fluorescent powders do not have to be mixed with silica gel, and the quantum-dot fluorescent powders are mixed with the gel material (the ultraviolet (UV) curable adhesive or the infrared (IR) curable adhesive) which can be mixed with quantum-dot fluorescent powders more evenly such that the quantum-dot fluorescent powders will not aggregate.

The following content will introduce a manufacturing method for the quantum-dot glass box 10 described above. With reference to the process flow chart in FIG. 6, the method comprises steps of:

S101: preparing and manufacturing a glass box having a receiving cavity and an injection inlet. As shown in FIG. 5, the glass box 11 is provided with a receiving cavity 111 and an injection inlet 112 communicated with the receiving cavity 111.

S102: preparing and manufacturing fluid-shaped quantum-dot fluorescent powder material. Specifically, first, respectively obtaining quantum-dot fluorescent powders and a gel material having a predetermined weight ratio; then, mixing the quantum-dot fluorescent powders with the gel material, and stirring evenly.

S103: injecting the fluid-shaped quantum-dot fluorescent powder material into the receiving cavity through the injection inlet.

S104: applying a curing process to cure the fluid-shaped quantum-dot fluorescent powder material in the receiving cavity. Wherein, the curing process can be selected from an infrared ray curing process, a ultra-violet ray curing process or a thermal curing process.

S105: hot melting and sealing the injection inlet in order to obtain the quantum-dot glass box.

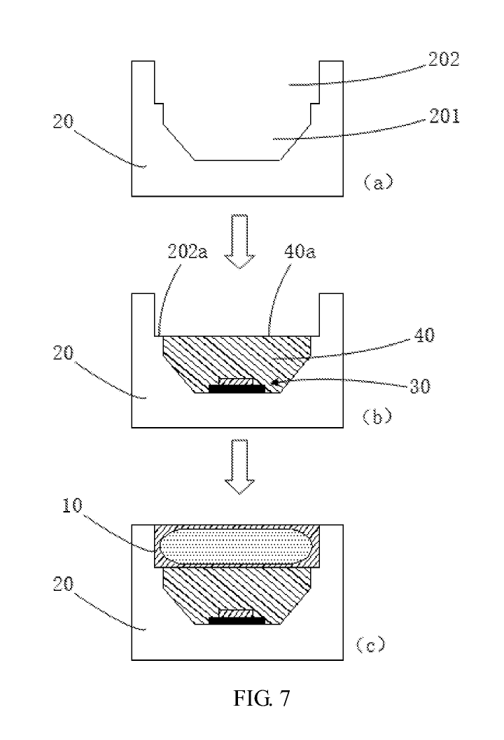

The present embodiment also provides a packaging method for an LED light source structure. With reference to FIG. 7, the packaging method specifically includes: providing a fixing bracket 20, wherein, from a bottom to a top of the fixing bracket 20, the fixing bracket 20 is sequentially provided with a packaging slot 201 and an installation slot 202, as shown at a portion (a) of FIG. 7. Next, utilizing a packaging gel 40 to package an LED chip 30 into the packaging slot 201, as shown in a portion (b) of FIG. 7. An upper surface 40a of the packaging gel 40 is not higher than a bottom 202a of the installation slot 202 (in the present embodiment, the upper surface 40a of the packaging gel 40 is flush with the bottom 202a of the installation slot 202). The packaging gel 40 can be a silica gel. Finally, the quantum-dot glass box 10 is clamped and placed in the installation slot 202, as shown in a portion (c) of FIG. 7. The installation slot 202 has a size matching with the quantum-dot glass box 10. The installation slot 202 can clamp and fix the quantum-dot glass box 10. In another embodiment, in order to connect the quantum-dot glass box 10 and the installation slot 202 more securely, a double-sided adhesive can be provided at a bonding position of the quantum-dot glass box 10 and the installation slot 202.

The LED light source structure and the corresponding packaging method described above combine an LED light source with the quantum-dot technology. Wherein, the quantum-dot fluorescent powder material is cured and packaged in the glass box in order to resist water and moisture, prevent the quantum-dot fluorescent powders from being oxidized and failure, and extend the life of the quantum-dot fluorescent powders. Comparing to the conventional art, the present invention effectively solves the problems of the short life of the quantum-dot fluorescent powders, low light emitting efficiency, and poor light color uniformity.

It should be noted that, herein, relational terms such as first and second, and the like are only used to distinguish one entity or operation from another entity or operation. It is not required or implied that these entities or operations exist any such relationship or order between them. Moreover, the terms “comprise,” include,” or any other variation thereof, are intended to cover a non-exclusive inclusion, such that a series of elements including the process, method, article or device that includes not only those elements but also other elements not expressly listed or further comprising such process, method, article or device inherent elements. Without more constraints, by the statement “comprises one . . . ” element defined does not exclude the existence of additional identical elements in the process, method, article, or apparatus.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A Light Emitting Diode (LED) light source structure, comprising:
a fixing bracket having a packaging slot and an installation slot from a bottom portion to a top portion of the fixing bracket, wherein a width of the installation slot is greater than a width of the packaging slot;
an LED chip;
a packaging gel; and
a quantum-dot glass box;
wherein, the LED chip is packaged into the packaging slot by the packaging gel; the installation slot has a size matching with the quantum-dot glass box; the quantum-dot glass box is clamped and placed in the installation slot; and
wherein, quantum-dot glass box includes a glass box and a quantum-dot fluorescent powder material, the glass box has a receiving cavity, and the quantum-dot fluorescent powder material is cured and packaged in the receiving cavity.

2. The LED light source structure according to claim 1, wherein, a wall thickness of the glass box is ranged from 0.1 mm to 0.7 mm.

3. The LED light source structure according to claim 1, wherein, the quantum-dot fluorescent powder material includes a gel material and quantum-dot fluorescent powders mixed in the gel material.

4. The LED light source structure according to claim 3, wherein, in the quantum-dot fluorescent powder material, a weight percentage of the quantum-dot fluorescent powders is ranged from 1% to 20%.

5. The LED light source structure according to claim 4, wherein, the quantum-dot fluorescent powder is CdSe/ZnSe, CdSe/ZnS, CdS/ZnS, CdS/HgS, CdSe/ZnS/CdS, CdSe/CdS/ZnS, InP/CdS, CuInS or Graphene Oxide quantum dot.

6. The LED light source structure according to claim 4, wherein, the gel material is an ultraviolet (UV) curable adhesive or an infrared (IR) curable adhesive.

7. The LED light source structure according to claim 1, wherein, the LED chip includes a printed circuit board and an LED lamp electrically connected with the printed circuit board.

8. The LED light source structure according to claim 7, wherein, the LED lamp is a blue LED lamp or an ultraviolet LED lamp.

9. The LED light source structure according to claim 1, wherein, an upper surface of the packaging gel is not higher than a bottom of the installation slot, and the packaging gel is a silica gel.

10. A packaging method for an LED light source structure, comprising steps of:
(a) providing a fixing bracket, wherein the fixing bracket has a packaging slot and an installation slot from a bottom portion to a top portion of the fixing bracket, and a width of the installation slot is greater than a width of the packaging slot;
(b) utilizing a packaging gel to package an LED chip into the packaging slot; and
(c) clamping and placing a quantum-dot glass box in the installation slot;
wherein, quantum-dot glass box includes a glass box and a quantum-dot fluorescent powder material, the glass box has a receiving cavity, and the quantum-dot fluorescent powder material is cured and packaged in the receiving cavity.

11. The packaging method for an LED light source structure according to claim 10, wherein, a wall thickness of the glass box is ranged from 0.1 mm to 0.7 mm.

12. The packaging method for an LED light source structure according to claim 10, wherein, the quantum-dot fluorescent powder material includes a gel material and quantum-dot fluorescent powders mixed in the gel material.

13. The packaging method for an LED light source structure according to claim 12, wherein, in the quantum-dot fluorescent powder material, a weight percentage of the quantum-dot fluorescent powders is ranged from 1% to 20%.

14. The packaging method for an LED light source structure according to claim 13, wherein, the quantum-dot fluorescent powder is CdSe/ZnSe, CdSe/ZnS, CdS/ZnS, CdS/HgS, CdSe/ZnS/CdS, CdSe/CdS/ZnS, InP/CdS, CuInS or Graphene Oxide quantum dot.

15. The packaging method for an LED light source structure according to claim 13, wherein, the gel material is an ultraviolet (UV) curable adhesive or an infrared (IR) curable adhesive.

16. The packaging method for an LED light source structure according to claim 10, wherein, the LED chip includes a printed circuit board and an LED lamp electrically connected with the printed circuit board.

17. The packaging method for an LED light source structure according to claim 16, wherein, the LED lamp is a blue LED lamp or an ultraviolet LED lamp.

18. The packaging method for an LED light source structure according to claim 10, wherein, an upper surface of the packaging gel is not higher than a bottom of the installation slot, and the packaging gel is a silica gel.
